(19) United States
(12) Patent Application Publication
(10) Pub. No.: US 2015/0203955 A1
(43) Pub. Date: Jul. 23, 2015

(54) APPARATUS AND METHOD FOR MAKING COMPOSITION SPREAD ALLOY FILMS

(71) Applicant: CARNEGIE MELLON UNIVERSITY, a Pennsylvania Non-Profit Corporation, Pittsburgh, PA (US)

(72) Inventors: Andrew J. Gellman, Pittsburgh, PA (US); James B. Miller, Madison, WI (US); Benoit G. Fleutot, Arras (FR)

(73) Assignee: CARNEGIE MELLON UNIVERSITY, a Pennsylvania Non-Profit Corporation, Pittsburgh, PA (US)

(21) Appl. No.: 14/535,644

(22) Filed: Nov. 7, 2014

Related U.S. Application Data
(60) Provisional application No. 61/962,458, filed on Nov. 7, 2013.

(51) Int. Cl. C23C 14/04; C23C 14/34

(52) U.S. Cl. CPC C23C 14/044; C23C 14/34

(57) ABSTRACT

The present invention describes the design, operation and performance of a new Composition Spread Alloy Film (CSAF) deposition having a rotatable shadow mask and capable of depositing CSAFs of at least two elemental components. The individual components can be deposited simultaneously from physical vapor deposition sources, such as, electron beams, effusion cells, and sputter sources, thus allowing preparation of CSAFs that can contain most metallic elements of the periodic table and other materials amenable to sputtering and physical vapor deposition techniques. Multicomponent materials with lateral composition gradients are deposited in such a way that both the direction and the amplitude of the composition gradient can be controlled independently for all components. An ultra-high vacuum chamber housing the apparatus can be used as a stand-alone device or interfaced with other vacuum chamber apparatus containing the tools for bulk and surface characterization necessary to establish the structure-composition-property relationships of a multicomponent alloy.

### CROSS-REFERENCE TO RELATED APPLICATIONS

This application claims the benefit under 35 U.S.C. §119 of U.S. Provisional Application Ser. No. 61/962,458, filed Nov. 7, 2013, which is incorporated by reference herein in its entirety.

### STATEMENT REGARDING FEDERALLY SPONSORED RESEARCH OR DEVELOPMENT

This invention was made with government support under the Department of Energy, National Energy Technology Laboratory under RES contract DE-FE0004000 and 41817M2053-RDS. The government has certain rights in this invention.

### FIELD OF THE INVENTION

The present invention relates generally to an apparatus used to manufacture composition spread alloy films and other multi-component materials. More specifically, the invention relates to an apparatus that allows the composition of materials deposited on a substrate to be varied through the use of a rotating shadow mask positioned between a vapor deposition source and the substrate. The invention further relates to a method of manufacturing a composition spread alloy film and other multi-component materials using a rotatable shadow mask.

### BACKGROUND OF THE INVENTION

Multicomponent materials, for example alloys such as AₓB₁₋ₓ and AₓB_{y}C_{1-x-y}, typically have useful properties that are superior to those of their pure components. However, the challenge in multicomponent materials development is that the exhaustive search of composition space to find the optimal composition for a given application can be experimentally daunting. The problem is that it requires the fabrication, characterization and study of large numbers of samples, each having a different composition. Furthermore, a key barrier to understanding the properties of multicomponent materials and developing them for specific applications is that many of their important properties are continuous functions of composition, (x, y). The composition dependence of these properties cannot be completely understood based solely on studies of a few single-composition samples. Understanding the characteristics and properties of multicomponent materials requires measurement and modeling methods that can span composition space.

Over the past decade, high throughput approaches for preparation and characterization of multicomponent materials have been developed to accelerate both materials science and the process of materials discovery and optimization. These high throughput methods have been popularized in the biomolecular sciences, catalysis, electrochemistry, photovoltaic sciences, and other areas of materials science. High throughput methods have three principal elements. The first is the preparation of large numbers of different materials samples that form the elements of a materials library. The second is the rapid, high throughput characterization of these materials to determine the composition, structure, phase distribution, and other qualities across the entire library. And the third is the ability to make high throughput measurements across the library of the materials properties relevant to the specific application of interest, such as catalytic activity, hardness, thermal conductivity, and other properties relevant to the specific application. The combined suite of capabilities can accelerate the study and development of multicomponent materials by orders of magnitude.

Many high throughput investigations of multicomponent materials use libraries based on composition spread alloy films, or CSAFs, which are thin alloy films deposited in such a way that there is a lateral gradient in their local composition. CSAFs are materials libraries that contain continuous composition distributions of binary or higher-order alloys on a single compact substrate. These can span entire composition spaces or focus on composition subspaces of interest. When spatially resolved methods are used to characterize their composition and functional properties, CSAF libraries allow rapid determination of composition-property relationships across broad, continuous regions of alloy composition space.

The use of CSAFs has a long history beginning in the 1950's and motivated by interest in the determination of alloy phase diagrams. Although the CSAF concept as a library or platform for accelerated study of multicomponent materials has existed for decades, early implementations were limited in scope and impact. To a large extent their use was limited by the availability of the complementary data acquisition and analysis tools needed for high throughput characterization. Key developments of the past decade have been increased availability of spatially resolving characterization tools and the computational tools for automated data acquisition and analysis.

Various metrics can be used to compare the merits of different CSAF deposition methods. One category of metrics describes the quality of the final CSAF. For example, one can consider the achievable composition span in the range x=0→1 for each component and the ability to control that composition span. Related to this is the purity of the film, or in other words, the minimization of contaminants. Another metric is the degree of component intermixing and thus, the ability to generate the thermodynamically stable phases associated with the local composition. A second category of metrics for comparison of different CSAF deposition methods are related to the method itself. This includes the set of different elements and materials that can be deposited by the given method and the number of elemental components and materials that can be included in a single CSAF or substrate. Related metrics include the range of attainable CSAF thicknesses and the growth rates. For many studies the physical size of the composition spread may be an issue. A third category of metrics includes issues of practicality and utility such as cost of the instrumentation, complexity and throughput. Needless to say, no single method for CSAF preparation scores perfectly across all metrics.

One previously disclosed approach, as shown in FIG. 2A, uses chemical vapor deposition (CVD) to produce composition spreads by positioning the CVD precursor outlets close to the substrate and allowing diffusive, gas phase intermixing to create the composition gradient on the substrate in the region between the two sources. The local film growth rate is dependent on the precursors, their flux to the substrate surface and the substrate temperature. This method is relatively simple and does allow co-deposition of components for intimate mixing. However, it allows limited control of the composition span for a given film and generates films of non-uniform thickness.

A second prior approach, presented in FIG. 2B, uses sources that give a uniform flux to the substrate and a contact mask which slides across the substrate surface to vary the effective deposition time, and thus, the thickness at different locations on the substrate. The CSAFs are generated by sequential deposition of components with gradients in different directions. One of the limitations of this method is that the components cannot be co-deposited and subsequent annealing may not lead to complete mixing, unless each layer is no more than one atomic monolayer in thickness. On the other hand, it does allow a very high degree of control over the direction and the span of the composition gradient. It also allows the composition to have arbitrary (but monotonic) variation across the substrate.

Another method for forming CSAFs is to use off-axis sources, as shown in FIG. 2C. In this method, sources are positioned off-axis relative to the substrate surface. This results in gradients in their flux across the substrate. CSAFs are formed by intermixing of fluxes from multiple sources. A simple, compact offset filament deposition tool with multiple sources is capable of repeatable, quantitative production of thin (≦100 nm) CSAFs on substrates that are up to ˜12 mm across, as one example. The system can be used to deposit any metal or other material that is evaporable at temperatures below ˜1500 K. It can produce fluxes that vary by over an order of magnitude across the substrate surface. This design has a number of merits but some limitations in functionality. One benefit over the masking method is that it has no moving parts. In general, the offset source methods have the benefit of allowing co-deposition of several components, but they do not allow the full span of composition space to be accessed on a single CSAF. FIG. 3 illustrates the composition spread of a typical CSAF created using the off-set filament deposition tool. The limited coverage of composition space shown in FIG. 3 is typical of CSAF deposition methods that do not have some means of reducing the flux of each component to zero at some point across the CSAF. Although the region spanned by a single CSAF can be controlled by controlling the source fluxes, no single CSAF generated by the offset source method can span the entire ternary composition space.

A shadow mask method, as shown in FIG. 2D, uses multiple sources operating simultaneously with shadow masks positioned between the sources and the substrate. A deposition method of this type is disclosed in U.S. Pat. No. 8,163,337 to Guerin, et al. Because the source has finite width and the shadow mask is positioned between the source and the substrate, different points on the substrate are shadowed from varying portions of the source. The umbra of the shadow creates a linear gradient in flux varying from a maximum at points exposed to the entire source to zero at points completely shadowed from the source. With no moving parts, this technique allows simultaneous deposition of multiple components across the substrate with linear gradients in composition along directions dictated by the positioning of the masks. The shadow mask CSAF deposition method allows co-deposition of components with flux gradients that generate CSAFs that span the entire composition space. However, the flux gradient is fixed and cannot be varied during the deposition process. It would therefore be advantageous to develop an apparatus and method for depositing a multiple component film or creating a CSAF which span the entire composition space, but that are also capable of varying the flux gradients to expand the physical extent across the film substrate of a particularly interesting region of composition space.

### BRIEF SUMMARY OF THE INVENTION

Composition Spread Alloy Films (CSAFs) are materials libraries used for high throughput investigations of multicomponent materials, such as alloy AₓB_{y}C_{1-x-y}. CSAFs are prepared such that the alloy film has a lateral spatial gradient in its local composition, thus they include a set of alloy samples with a distribution of compositions that spans a continuous region of composition space, (x,y). The present invention is based on the shadow mask concept for generating composition gradients, but modified to allow rotation of the shadow mask during deposition. In one embodiment, for a film containing at least two components, rotatable shadow masks are positioned between each of two vapor deposition sources and the deposition substrate. In this embodiment, co-deposition of any combination of at least two components can be accomplished. In the case of ternary AₓB_{y}C_{1-x-y} CSAFs, the present invention allows the three components to be deposited such that the resulting CSAF spans the entire ternary alloy composition space (x=0→1, y=0→1−x) and, furthermore, contains all three binary alloys AₓC₁₋ₓ, and BₓC₁₋ₓ (x=0→1) and all three pure components. In yet another embodiment, the present invention allows preparation of multiple component films that magnify selected regions of the composition space, (x=xₘᵢₙ→xₘₐₓ, y=yₘᵢₙ→1−x).

The apparatus and method of the present invention have a number of advantages over the methods illustrated in FIG. 2. Principally, in one CSAF, all possible compositions of a ternary system can be prepared: the pure components; all possible binary compositions, and all possible compositions of a ternary alloy, as shown in FIGS. 1 and 8. Moreover, the orientation of the shadow mask can be manipulated before and during the deposition process to control the amplitude and orientation of the composition gradient across the substrate. Indeed, by rotating the mask during deposition the composition gradient can be controlled to give uniform composition, a composition varying from 0 to 100% across the film, or any range in between. The apparatus and method of the present invention works for metals as well other materials that can be deposited via vapor deposition. The present invention, coupled with the ability to perform spatially resolved analysis, allows for a comprehensive study of a number of surface science and materials science problems that are otherwise intractable.

### BRIEF DESCRIPTION OF THE SEVERAL VIEWS OF THE DRAWING

FIG. 1A is a schematic representation of a CSAF generated by the apparatus and method of the present invention with regions containing the entire ternary alloy composition space, AₓB_{y}C_{1-x-y} (x=0→1, y=0→1−x), all three binary alloys AₓB₁₋ₓ, AₓC₁₋ₓ, and BₓC₁₋ₓ (x=0→1), and all three pure components.

FIG. 1B is a photograph of a CuₓAu_{y}Pd_{1-x-y} CSAF.

FIGS. 2A-D are schematic representations of four methods for generating composition spread alloy films: chemical vapor deposition sources positioned close to the substrate, deposition of individual components in wedges using a sliding contact mask, offset positioning of sources to generate non-uniform flux distributions across the substrate surface, and simultaneous deposition of multiple components using fixed shadow masks.

FIG. 3 is an illustration of the region of a ternary alloy composition space spanned by a CSAF generated using an offset filament CSAF deposition tool, with the composition ranges of each of the three components shown.

FIG. 4 is a schematic of the rotating shadow mask CSAF deposition tool, according to one embodiment of the present invention.

FIG. 5A is a three dimensional rendering of one embodiment of the present invention.

FIG. 5B is a three dimensional rendering of the deposition tool inside an ultra-high vacuum chamber.

FIGS. 6A-C are different views of the copper (Cu) composition profile measured using energy dispersive x-ray (EDX) analysis from a single component copper (Cu) film deposited with the rotatable shadow mask of the present invention fixed in one direction.

FIG. 6D is a cross section of the copper (Cu) composition profile along the gradient direction.

FIG. 7A is a copper (Cu) composition profile measured using EDX analysis of a single component Cu film deposited with continuous rotation of the shadow mask during the deposition, according to one embodiment of the present invention.

FIG. 7B is a copper (Cu) composition profile along the source inclination direction.

FIGS. 8A-C show different views of compositions measured by EDX of a CuₓPd_{y}Au_{1-x-y} CSAF, created in accordance with one embodiment of the present invention.

FIG. 8D is a distribution of CSAF compositions across a ternary composition diagram measured at multiple points on a CSAF created according to an embodiment of the present invention.

FIG. 9 depicts components of an alternative embodiment of the apparatus.

FIG. 10 is a three dimensional rendering of the mechanism to control rotation of the shadow mask.

FIG. 11 depicts a cross-section of components of an alternative embodiment of the present invention.

### DETAILED DESCRIPTION OF THE INVENTION

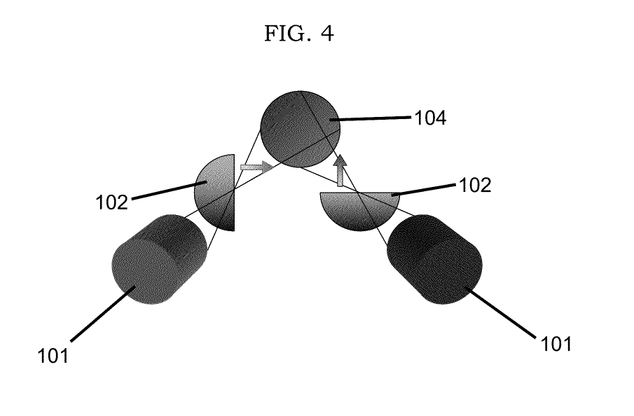

In one embodiment of the present invention, an apparatus for creating a composition spread film comprises a vapor deposition source 101 and at least one shadow mask 102 positioned to block at least a portion of the flux emitted from the source 101. In the preferred embodiment, shadow mask 102 is connected to rotating mechanism 103, such that the shadow mask 102 is able to rotate about an axis 201. As shown in FIG. 4, shadow mask 102 is a semicircle. That is, shadow mask 102 is one half of a disk. Shadow mask 102 can be other shapes, as long as a portion of the flux from source 101 is blocked by the mask 102 and the remaining portion of the flux is able to contact substrate 104. The source 101, mask 102, rotating mechanism 103, and substrate 104 are contained within an ultra-high vacuum chamber 106 in the preferred embodiment. However, the method and apparatus of the present invention can be utilized in connection with low pressure deposition techniques as well.

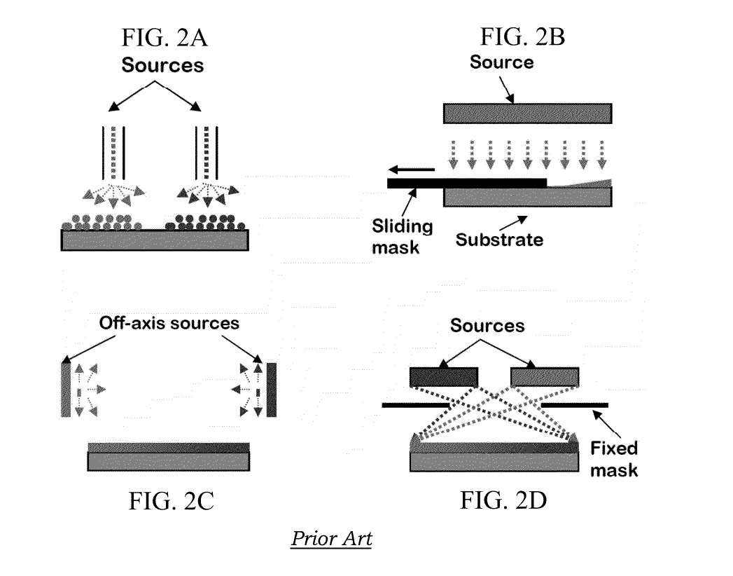

Referring to FIG. 2D, it is shown that the positioning of a shadow mask 102 between the source 101 and the substrate 104 determines the location and the spatial extent of the flux gradient at the surface of substrate 104. Moreover, FIG. 4 depicts an embodiment of the present invention in three dimensions where it is shown that the orientation of the shadow mask 102 can also be used to control the direction of the flux gradient across the substrate 104. For example, in FIG. 4, one source will have a gradient from left to right because the mask 102 blocks the left portion of the flux. The other source 101 in FIG. 4 will have a gradient from top to bottom as the mask 102 blocks the lower half of the flux from this source 101. However, in both examples, the flux gradient is fixed depending on the location of the mask 102 relative to the substrate 104 and source 101. In other words, if the mask 102 is shifted in one direction, the gradient will move in the same direction.

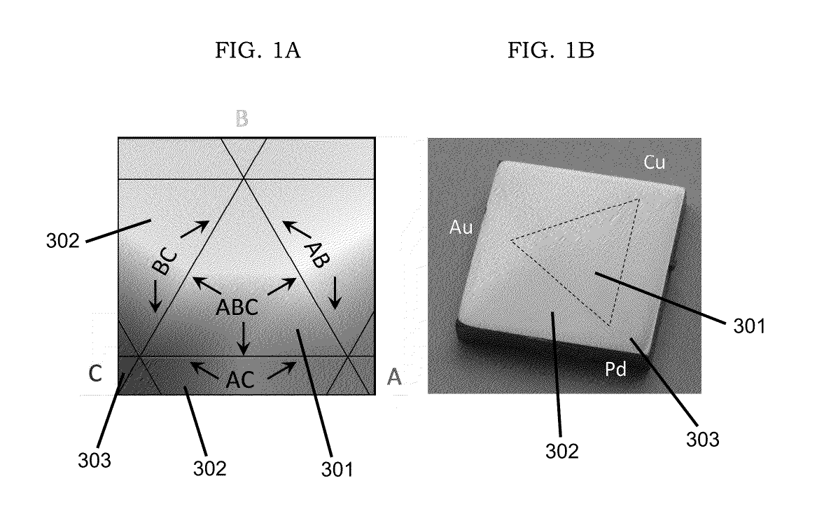

According to embodiments of the present invention, shadow mask 102 is rotated about axis 201 during deposition to control the net flux at either end of the gradient spread. One of the beneficial features of an apparatus of the present invention, in which shadow mask 102 is rotated, is that with three active sources 101, the flux gradients can be oriented at 120° from one another to create a composition distribution resembling a triangular ternary composition diagram. In fact, the flux field can be established such that it produces a CSAF with the composition depicted in FIG. 1A. The middle section of the diagram depicted in FIG. 1A is the triangular region 301 that spans all of ternary alloy composition space, AₓB_{y}C_{1-x-y} with x=0→1 and y=0→1−x. For example, for a CSAF comprised of gold (Au), copper (Cu), and palladium (Pd), the center region 301 will contain amounts of all three metals such that all possible combinations of relative concentrations are represented somewhere within the triangle. A substrate containing these three metals is shown in FIG. 1B, with the center triangular region 301 superimposed on the CSAF for illustrative purposes.

Referring again to FIG. 1A, the regions outside the edges of the ternary triangle region 301 contain all three binary composition spreads, AₓB₁₋ₓ, AₓC₁₋ₓ, and BₓC₁₋ₓ with x=0→1. Binary regions 302 are labeled AB, BC, and AC on FIG. 1A. Outside the vertices of the ternary triangle region 301 are regions 303 (not points) that contain only the pure components, A, B, or C. Having regions 303 that contain the pure components becomes extremely useful for calibration of the analytical tools that are used to characterize the composition spread film. Equally importantly, the fact that the shadow masks 102 can be rotated during deposition means that the composition range spanned by the ternary triangle region 301 can be controlled to span any subspace of the ternary composition space, AₓB_{y}C_{1-x-y} with x=xₘᵢₙ→xₘₐₓ and y=yₘᵢₙ→(1−xₘₐₓ). This effectively magnifies the selected region of composition space to occupy the full triangular region 301 in the middle of the composition spread film.

Magnifying a selected region of composition space requires controlling the fluxes from each of the sources 101. This is accomplished by rotating each shadow mask 102 for a given source 101 during the deposition. The shadow mask for each source would run through a large number of cycles, N, during each deposition. During each cycle, the shadow mask would be programmed to be positioned at one orientation for a period t1 and then rotate through 360 degrees for a time t2. The total deposition time would be N(t1+t2). The cycle time t1+t2 should be chosen such that <1 nm of material is deposited per cycle. The fluxes, the number of cycles, t1 and t2 would be chosen independently for each source to achieve the desired composition spread.

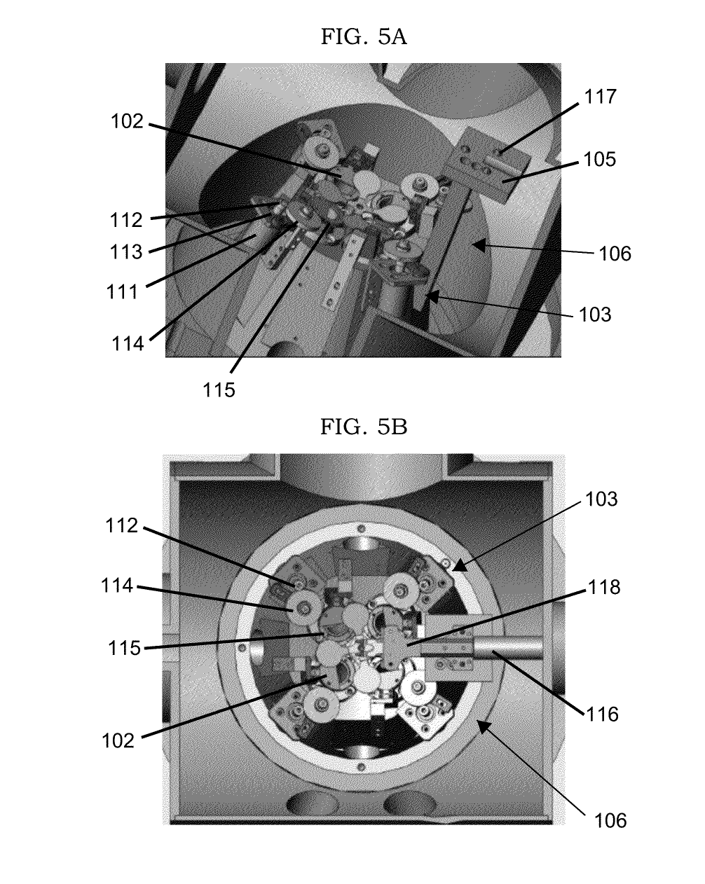

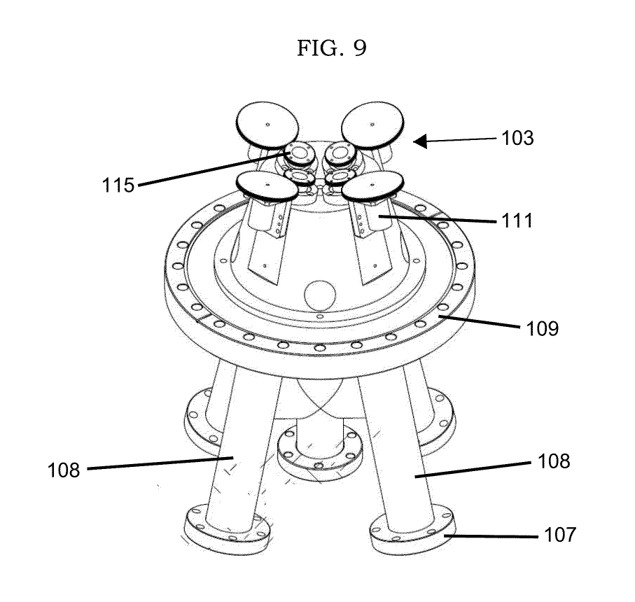

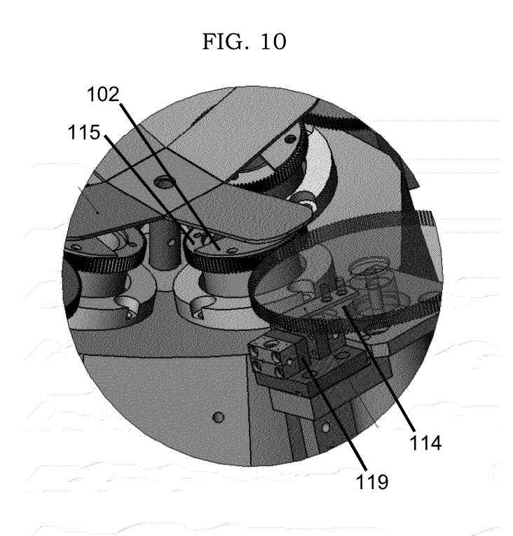

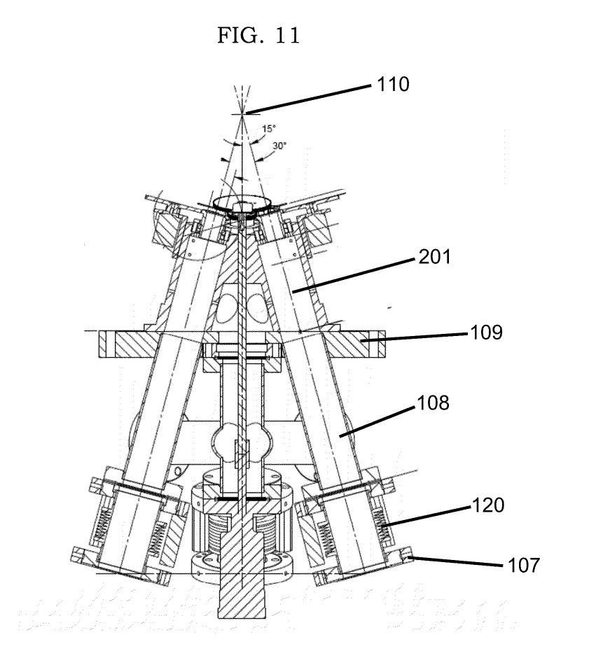

In one specific embodiment, the rotating shadow mask film deposition apparatus is adapted to be mounted on a center flange 109 used in connection with a vacuum chamber 106. In the preferred embodiment, center flange 109 is a standard 254 mm CONFLAT® (CF) flange. The apparatus can be mounted on flanges of other dimensions as well, depending on the particular application or equipment. FIG. 5 shows the apparatus mounted in a vacuum chamber 106. As further shown in FIG. 9, the apparatus can have four material vapor sources 101 mounted or recessed in tubes 108. Flanges 107 are disposed on one end of tubes 108 and can provide an attachment point for source 101. In the preferred embodiment, flanges 107 are 70 mm CF flanges and tubes 108 are angled at 15° from the normal of center flange 109. The sources 101 are aimed at a point 110 that is a distance from the face of flange 109 along its center line. The sources 101 can be tilted at other angles, within the limit that the source 101 must be in line with substrate 104 and capable of depositing a material on the substrate 104. For example, if six sources 101 are used, they will have to be spaced further apart (and further from the center line), requiring a tilt of greater than 15° from the normal. That is, the angle of a source 101 will be dependent on its placement.

Within vacuum chamber 106, substrate 104 is positioned so that focal point 110 is located on the surface of substrate 104. The substrate 104 is shadowed from the four sources 101 by four independently rotatable masks 102 that are rotated by rotating mechanism 103. That is, each shadows mask 102 is positioned between its respective source 101 and point 110. In the preferred embodiment, rotating mechanism 103 is comprised of geared stepper motors 111 adapted for use in a vacuum chamber 106. Stepper motors 111 contain a gear 112 at its terminal end 113, which contacts intermediate gear 114. Intermediate gear 114, in turn, engages gears disposed on ring or cylinder 115. Ring 115 is mounted coaxially with source 101 in a manner that allows it to rotate when driven by the other components of rotating mechanism 103. As shown in FIG. 5, the shadow mask 102 is mounted to ring 115. While ring 115 is disclosed for the preferred embodiment, other carriers for mask 102 can be utilized as long as mask 102 is able to rotate about an axis when driven by motor 111. Alternatively, motors 111 are located outside of the vacuum chamber 106 and are mechanically connected to ring 115. A person of ordinary skill in the art will appreciate that several types of mechanisms 103 can be used to control the rotation of the shadow masks 102.

Referring again to FIGS. 5A and 5B, each source has its own shadow mask 102 and rotating mechanism 103. While this particular embodiment shows a single shadow mask 102 for each source 101, multiple shadow masks 102 can be used for the same source 101. In this example, the masks 102 could be controlled to completely block the source 101 and would be useful for creating layers on the substrate 104. The stepper motors 111, or other rotation controllers, are capable of rotating the shadow masks 102 independently for each source 101 and under computer control. In alternative embodiments, a sensor 119 is provided to indicate the rotation speed and position of shadow masks 102.

By way of example of relative sizes and spacings between components, an apparatus as described in the preferred embodiment can have electron beam sources 101 with diameters of 5 mm and the distance from the sources 101 to the substrate 104 can be 135 mm. In this example, rotating shadow mask 102 is positioned 45 mm from the source 101. Further, an apparatus having the configuration as described in this paragraph results in a linear flux gradient across a 10 mm region of the substrate 104. Provided that the sources 101 are aligned such that the spatial extent of the gradient lies within the dimensions of the substrate 104 and that the shadow masks 102 are oriented at 120° from one another, a CSAF of the type illustrated in FIG. 1A can be deposited on the substrate 104. The width of the gradient is controlled by the distances from source 101 to shadow mask 102 and the distance from shadow mask 102 to substrate 104. As a result, these figures represent one particular setup and other sizes and spacings can be used. However, note that source 101 must have a finite dimension; in other words, source 101 cannot be a point source. A person of ordinary skill in the art will recognize that the physical width of the variable part of the composition spread on the substrate depends, in part, on the size of the aperture of the source 101. Further, as can be seen in FIG. 4, the flux leaving the source 101 cannot be collimated. Within these parameters, a wide range of sizes can be utilized.

In one embodiment, the substrate 104 is a 14×14 mm square of 2 mm thick molybdenum (Mo). Molybdenum is chosen for most substrates because very few metals will alloy with it during heating. The 14×14 mm format is small relative to that of traditional CSAF deposition tools. However, provided that the spatial resolution of methods used to study the CSAF allow sufficient composition resolution, the smaller size can be beneficial. For example, the benefits of a smaller substrate size include easier handling of CSAF samples during analysis and allowing for a compact design of the apparatus of the present invention.

Several types of vapor deposition sources 101 can be used, such as electron beams, mini-electron beams, effusion cells, sputter sources, magnetron sputter sources, reactive and non-reactive sources, Knudsen sources, and evaporators. In the preferred embodiment, electron beam sources 101 are chosen because they allow deposition of elements from a very large part of the periodic table. As an example, commercially available Mantis Deposition Ltd. mini electron beam (e-beam) sources 101 specially fitted with large (5 mm) apertures can be used. These particular e-beam sources 101 give flat source profiles. The sources 101 are ‘flat’ in that they emit their materials across a finite area rather than being point sources. The sources 101 can be mounted on bellows 120 connected to flange 107 that allow a small degree of tilt for alignment purposes. By allowing a limited range of movement on flange 107, a laser mounted on the source flange 107 can be used to align the source flanges 107 with the center of the substrate 104.

In the preferred method of creating a CSAF or multiple component material according to the present invention, the fluxes from multiple sources 101 are calibrated to give roughly equal fluxes at the center of the substrate 104. To obtain all compositions of a ternary material, for example, the fluxes are held constant during the deposition process. In this example, the vacuum chamber 106 houses a MAXTEK™ quartz crystal microbalance (QCM) mounted on an xyz manipulator that allows the QCM to be positioned at the focal point 110 for flux measurement during source 101 calibration or moved out of the way during deposition. The QCM is used to calibrate the deposition rate of each component independently. The QCM also allows calibration of the ion flux monitors that are integral to certain types of electron beam sources 101. The power to each source can be controlled using the signal from the ion flux monitor to keep the source flux constant during the deposition process.

In an alternative embodiment, the substrate 104 is mounted on a holder 118, which is connected to a manipulator 116. The manipulator 116 positions the substrate 104 accurately and reproducibly in front of the sources 101 by aligning with a reference point on the stage 105. Preferably, the reference points are pins 117 contained on stage 105 that mate with recesses contained on the surface of manipulator 116. As shown in FIG. 5A, stage 105 and pins 117 are fixed to the main body of the apparatus. As such, the position of these components does not change relative to sources 101. Alternatively, stage 105 can be attached to the walls of chamber 106. In either method of attachment, it is important that stage 105 and pins 117 function as a reference point. Pins 117 are disclosed in the preferred embodiment, but other reference devices, such as slots, tabs, or keys, can be used as long as manipulator 116 can accurately and repeatedly position holder 118 on stage 105. Alternatively, the substrate manipulator 116 has power and thermocouple contacts to allow heating of the substrate 104 prior to or during the deposition process. In yet another embodiment, the manipulator 116 is designed to allow transfer of the substrate holder 118 to a CSAF analysis systems integrated in chamber 106. Examples of such analysis systems include a THERMO SCIENTIFIC™ Theta Probe and a TESCAN VEGA3™ scanning electron microscope.

In the preferred embodiment, the vacuum chamber 106 can be evacuated to pressures <10⁻⁹ Torr using a 500 l/sec turbomolecular pump. If evaporative sources 101 are used, the apparatus is mounted at the bottom of chamber 106 because the sources can contain liquid metals during operation. Conversely, when using sputter deposition sources 101, any orientation can be used. In addition to the tools mentioned above, the chamber 106 can be equipped with an ionization pressure gauge, a leak valve to allow controlled introduction of gases, an Ar⁺ ion gun for sputter cleaning of the substrate 104 and a residual gas analyzer for analysis of background gases and detection of leaks.

The characteristics of the CSAF can be controlled by varying the rates of deposition of the various components, the thickness of the film, and the composition distribution. For example, in a preferred embodiment of the method, the deposition rate is adjusted to allow the deposition of CSAFs with requisite thickness to be created in a reasonable period of time, such as 1-10 hours. For example, a CSAF thickness of a few nanometers could be sufficient for applications in which only the surface properties are important. On the other hand, a thickness on the order of a few microns might be necessary if the property of interest is dominated by bulk materials characteristics. As another example, dewetting is found to be a critical issue if thin CSAF's are annealed to high temperatures. Dewetting of the CSAFs renders them useless for many investigations but can be avoided by attention to the thickness of the film. In each of these examples, the thickness of the film can be adjusted by rotating the mask 102 during the deposition process.

The following will describe specifics as an example of one particular embodiment of the present invention. This particular embodiment is illustrated in FIGS. 5 and 9. In this example, commercial mini electron beam evaporators are used as sources 101 and can deposit many metals and other materials at rates of ˜1 monolayer per second at a source 101 to substrate 104 working distance of 135 mm. In this particular example, the deposition of a 1 μm thick CSAF can be accomplished in the space of a few hours. To create a CuₓAu_{y}Pd_{1-x-y} CSAF in this example, copper, gold, and palladium pellets with 3 mm diameter and 99.99% purity are placed in molybdenum crucibles of three electron beam evaporation sources 101. The sources 101 are then aligned and the flux versus power curves are calibrated independently, before depositing the CuₓAu_{y}Pd_{1-x-y} CSAF.

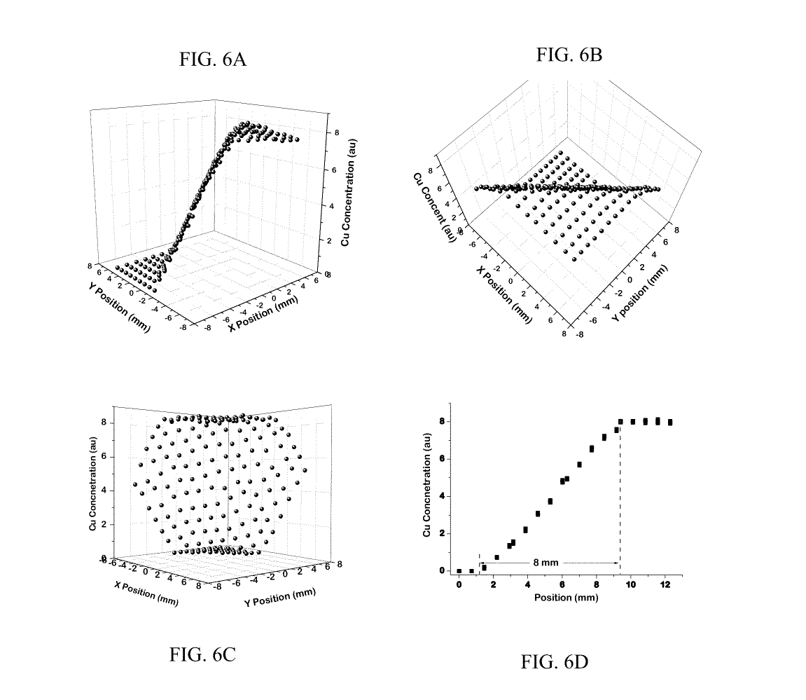

Creating a CSAF according to the method of the present invention has the benefit that the deposition flux across the substrate 104 is linear in position. The linear nature of the deposition flux is illustrated in FIG. 6. For example, in FIG. 6D, the concentration of copper increases at a continuous rate as the position increases. In this preferred method, each source 101 and its corresponding mask 102 are aligned such that the midpoints of the gradients from all sources 101 intersect at point 110, which is on the surface and near the center of the substrate 104. To allow for proper alignment, each of the four source flanges 107 has a bellow 120 that allows a small degree of tilt for source alignment. A laser alignment tool is used to align the source flanges 107 with focal point 110 on the deposition substrate 104. The laser beam is normal to the flange 107 and co-linear with its center line. The laser beams from all four source flanges 107 must fall on the same point on the substrate 104.

Furthermore, in the preferred embodiment, the shadow mask 102 intersects half of the source beam at all shadow mask 102 orientations. That is, at all times 50% of the flux from the source 101 is blocked by the mask 102. As shown in FIG. 5, this orientation results in mask 102 bisecting the aperture which the mask 102 blocks. In this configuration of the preferred embodiment, the axis of rotation 201 of the mask 102 is coextensive with a line from point 110 to source 101. Alternatively, the mask can block a portion of the flux greater than or less than 50% and its axis 201 can be offset from the center of source 101. Fortunately, the design of the apparatus is tolerant of minor misalignments because these simply shift the spatial extents of the composition spreads from each of the four sources 101. Provided that the maximum and minimum edges of the flux spread from each source 101 lie on the substrate 104, a full ternary CSAF will be deposited on the face of a 14×14 mm² substrate 104 regardless of the presence of minor misalignments. For example, if the spatial extents of the gradients from the sources 101 are measured to be about 8 mm, as shown in FIG. 6D, then the triangular ternary alloy region 301 has edges of about 9 mm and falls well within bounds of the substrate 104 having a size of 14 mm×14 mm.

The alignment of the electron beam sources 101 is checked using a QCM that can be positioned at the focal point 110. The individual component deposition rates are calibrated by depositing single component films and using both EDX analysis (ex situ) and the QCM (in situ) to determine the film thickness and confirm the alignment of different sources with the substrate 104 and shadow masks 102, depending on the desired gradient type and deposition type. Source operating conditions are found that deliver fluxes that are sufficient for CSAF deposition and are high enough to be measured using the ion flux monitors on each of the sources 101. The current measured by the ion flux monitor is then used to control the source power to deliver constant flux. In tandem, these methods allow calibration of the single component deposition rates to an accuracy of <5%. The copper (Cu), gold (Au), and palladium (Pd) film composition distributions across the CSAF are determined using EDX analysis to verify the alignment of the sources 101, the rotatable shadow masks 102, and the substrate 104.

Referring now to FIG. 6, the composition of a single component (Cu) CSAF is shown. In this example, copper (Cu) is deposited onto the surface of a polished 14×14 mm² molybdenum substrate 104. The copper source 101 is outgassed before deposition to obtain flux readings arising solely from metal evaporation and not from materials outgassed by the source 101. As previously discussed, the composition spread has a linear gradient along the direction determined by the orientation of the shadow mask 102 and is constant in the orthogonal direction. There is a constant copper (Cu) concentration on one side of the gradient and no detectable Cu on the other side. Clearly, if the shadow mask is held in a fixed orientation during deposition, the composition spread varies linearly between 0 and 100% across the substrate 104. With the spacing previously identified in this example, the spatial extent of the gradient is 8 mm (see FIG. 6D) and it is centered on the substrate 104.

One of the key features of the apparatus and method is that rotation of the shadow mask 102 during deposition can be used to control the amplitude of the composition gradient. For example, if a semicircular mask 102 spends 50% of the time in one orientation and 50% of its time in continuous rotation, then the CSAF would have the same spatial extent as a CSAF wherein the mask 102 was not rotated, but its amplitude would go from 25% to 75% of a CSAF prepared using a fixed mask at the same deposition time and source operating conditions.

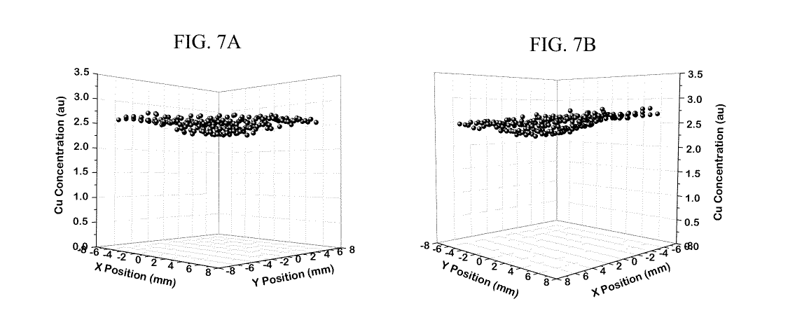

FIG. 7 shows an EDX map of a copper CSAF created by a method wherein mask 102 is rotated during the deposition process. In this example, a copper film has been grown while rotating the shadow mask at a constant rate of 12°/second. The EDX maps in FIG. 7 show that there is no net gradient in copper concentration across the substrate 104. That is, rotation of the mask 102 results in deposition of a fairly uniform film. If the mask 102 were rotated in a non-constant rate, a gradient would be present. Similarly, if no mask 102 were present, the amplitude would be greater. As can be shown in FIG. 7B, there is a slight gradient in film composition in the direction of source inclination. As described previously, the deposition tubes 108 are tilted by an angle of 15° with respect to the center line of the center flange 109, on which the main body of the apparatus is mounted. The flux at the surface of the substrate 104 depends on the distances between points on the substrate 104 and points across the surface of the source 101, thus causing a slight composition gradient in the tilt direction.

Creating a linear gradient in the alloy composition (elemental component fractions) requires that the deposition rates of the components be identical. It is not sufficient to simply have a linear gradient in the component fluxes. For example, consider the deposition of a binary CSAF, AₓB₁₋ₓ, where the two components are deposited from opposing directions. The distribution of A across the substrate is given by A(ξ)=ξ*A₀ and the distribution of B is B(ξ)=(1−*ξ)*B₀ where A₀ and B₀ are the maximum amounts of the two components deposited at either end of the substrate 104 and is the position on the substrate 104. Although the flux of each component is linear in the position, the fraction of A forming the alloy at a given position on the surfaces of substrate 104 is given by x(ξ)=ξ*A₀/(B₀+ξ*(A₀−B₀)). When A₀=B₀, the gradient in the component fraction across the substrate 104 is linear in position. However, the composition is clearly non-linear in position if A₀≠B₀. For ternary CSAFs generated by having three components deposited with fluxes at 120° from one another, the component fluxes at the three corners, or the pure component region 303 of FIG. 1, must be identical to give a CSAF with a linear gradient in composition such that the positions on the CSAF map directly onto a ternary composition diagram.

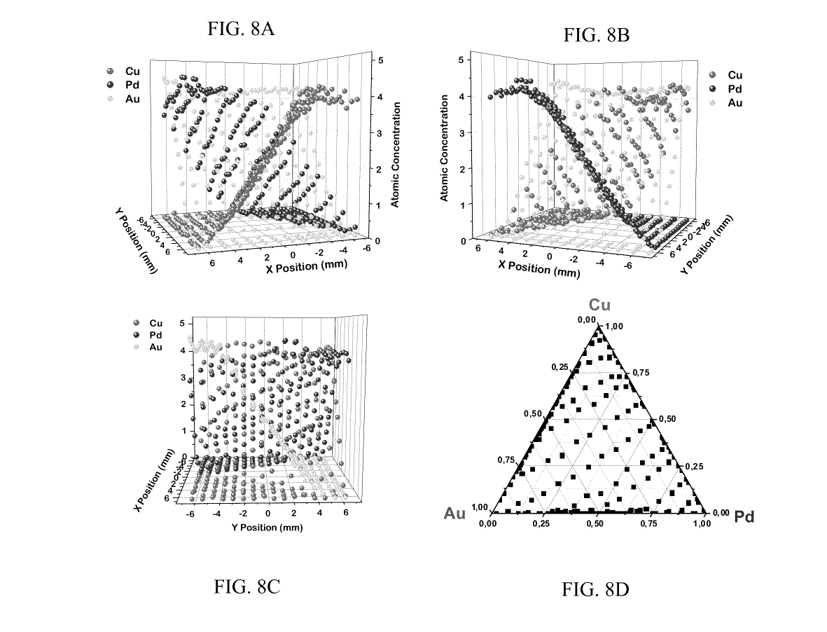

In an alternative embodiment, the apparatus can be tested to ensure its accuracy. The apparatus is tested by making a CuₓPd_{y}Au_{1-x-y} ternary CSAF with the shadow masks 102 oriented at 120° from one another. By way of a particular example, the gold (Au) source ion current measured by its flux monitor is 300 nA, the palladium (Pd) source current is 7.7 nA and the copper (Cu) source current is 3.5 nA. With these source settings, the deposition rates of all three metals are 2.2 nm/min and all three components are co-deposited for 45 min to generate a 100 nm thick CSAF. The results of this testing is shown in FIG. 8.

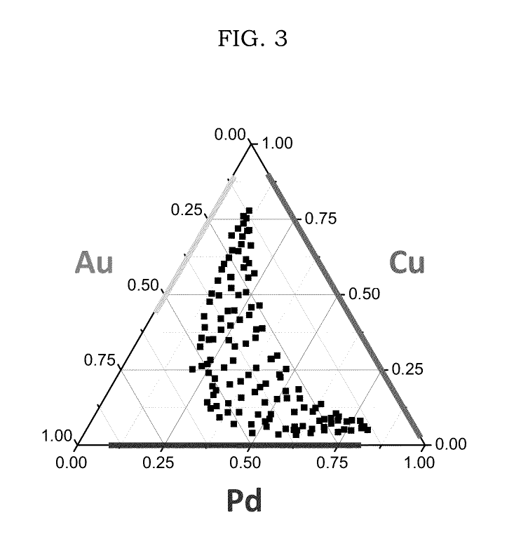

As illustrated in FIG. 8, the distribution of each component has a linear gradient along the expected direction with equal maximum amounts at the three corners 303 of the CSAF. Using EDX analyses, the local composition of the CSAF on a square grid with 1 mm spacing are measured and are shown on the ternary composition diagram depicted in FIG. 8D. In contrast to the composition spread prepared with the offset filament tool, as shown in FIG. 3, the ternary CSAF generated by the method of the present invention spans the entire ternary composition space. As further shown in FIG. 8, the uniform spacing of points across the ternary composition diagram indicates that the fluxes from each of the three sources are roughly equal. The high density of points along the edges (pure binaries) arises from the fact that, as illustrated in FIG. 1, there are regions of the CSAF where the flux from one source is zero and thus, only two components are deposited.

The apparatus of the present invention can be used as a stand-alone device. Alternatively, the apparatus can be attached to a scanning electron microscope with detectors for energy dispersive spectroscopy and electron backscatter that allow ready determination of phase diagrams across composition space. In another embodiment, the apparatus is attached to another apparatus for spatially resolved surface characterization by photoemission and ion scattering methods, to enable high throughput study of alloy surface phenomena such as segregation. In a third embodiment, the apparatus is coupled to a 10×10 multichannel microreactor array, to enable rapid study of alloy catalysis across composition space. In general, well characterized CSAFs of the type described can be used to accelerate the study of number bulk and surface phenomena.

While this invention has been illustrated and described primarily in terms of embodiments using CSAFs for applications in catalysis, those skilled in the art will recognize that the apparatus and method of the present invention could also be used for any thin film, surface, and materials science applications. Further, examples and references specifically made to alloys and CSAFs are equally applicable to non-metallic components. The invention is not intended to be limited to the details shown. Rather, various modifications may be made in the details without departing from the invention. In addition, while the disclosure has been described in detail and with reference to specific embodiments, the embodiments are examples only. Thus, it is intended that the present disclosure cover the modifications and variations of this disclosure provided they come within the scope of the appended claims and their equivalents.

What is claimed is:

1. An apparatus for depositing a film on a substrate, comprising:
a vapor deposition source having a vapor flux;
a mask positioned between the source and the substrate, wherein the mask blocks at least a portion of the vapor flux in a first position; and
a rotating mechanism adapted to rotate the mask about an axis to a second position.

2. The apparatus of claim 1, wherein the second position is substantially 360 degrees of rotation about the axis from the first position and wherein the mask blocks at least a portion of the vapor flux at all positions between the first position and the second position.

3. The apparatus of claim 1, wherein the axis is coextensive with a line extending from the source to the substrate.

4. The apparatus of claim 1, wherein the rotating mechanism comprises:
a cylinder having a first end and a second end,
wherein the mask is mounted to the first end,
wherein the second end is positioned towards the source;
wherein the cylinder is adapted to rotate around the axis; and
a motor in rotational engagement with the cylinder.

5. The apparatus of claim 1, further comprising:
one or more additional vapor deposition source having a vapor flux,
wherein each additional source is associated with an additional mask positioned between the additional source and the substrate,
wherein each additional source is associated with an additional rotating mechanism adapted to rotate the additional mask about an additional axis; and
wherein each additional source is aligned with the substrate.

6. The apparatus of claim 1, wherein the mask is a semicircle.

7. The apparatus of claim 1, wherein the mask bisects the vapor flux.

8. The apparatus of claim 1, wherein the vapor deposition source is selected from the group consisting of an electron beam evaporator, a Knudsen source, a magnetron sputtering source, a reactive sputtering source, a non-reactive sputtering source, and an evaporator.

9. The apparatus of claim 1, further comprising:
a stage disposed in a fixed position relative to the source;
at least one reference component associated with the stage;
a manipulator for positioning the substrate, wherein the manipulator is adapted to engage the at least one reference component to position the substrate in a known position relative to the source.

10. The apparatus of claim 9, wherein the at least one reference component is a plurality of pins and wherein the manipulator has a plurality of corresponding recesses adapted to engage the plurality of pins.

11. The apparatus of claim 1, further comprising:
a second vapor deposition source,
wherein the second source is associated with a second mask positioned between the second source and the substrate,
wherein the second source is associated with a second rotating mechanism adapted to rotate the second mask about a second axis,
wherein the second source is aligned with the substrate;
a third vapor deposition source,
wherein the third source is associated with a third mask positioned between the third source and the substrate,
wherein the third source is associated with a third rotating mechanism adapted to rotate the third mask about a third axis,
wherein the third source is aligned with the substrate; and
wherein the mask is oriented 120 degrees from the second mask and 120 degrees from the third mask.

12. The apparatus of claim 5, further comprising:
a center plate having a circular shape,
wherein the source and the one or more additional source are positioned at an equal distance from the center of the center plate and around the circumference of the center plate.

13. A method for depositing a film on a substrate, comprising:
providing a vapor deposition source having a vapor flux;
positioning the substrate at a distance from the source;
positioning a mask between the source and the substrate;
vaporizing material from the source, wherein the mask blocks at least a portion of the vapor flux; and
rotating the mask about an axis.

14. The method of claim 13 further comprising:
depositing a material on the substrate during mask rotation,
wherein the mask blocks at least a portion of the flux during rotation.

15. The method of claim 14, wherein the mask is continually rotated.

16. The method of claim 13 wherein the axis is coextensive with a line extending from the source to the substrate.

17. The method of claim 13, further comprising:
performing a cycle comprising:
depositing a material on the substrate for a first period of time prior to rotation of the mask;
depositing the material on the substrate for a second period of time during rotation of the mask; and
ceasing rotation of the mask.

18. The method of claim 17, wherein the thickness of material deposited during the first period of time and the second period of time is less than one nanometer.

19. The method of claim 18, further comprising repeating the cycle.

20. The method of claim 13, wherein the vapor deposition source is provided in a vacuum having a pressure less than 10⁻⁹ Torr.
